(19) United States
(12) Patent Application Publication
(10) Pub. No.: US 2021/0104560 A1
(43) Pub. Date: Apr. 8, 2021

(54) IMAGE SENSING DEVICE

(71) Applicant: SK hynix Inc., Gyeonggi-do (KR)

(72) Inventor: Ju Sang Lee, Chungcheongbuk-do (KR)

(21) Appl. No.: 16/786,671

(22) Filed: Feb. 10, 2020

(30) Foreign Application Priority Data
Oct. 4, 2019 (KR) 10-2019-0123172

(51) Int. Cl. H01L 27/146

(52) U.S. Cl. CPC H01L 27/14605; H04N 5/3741; H01L 27/14607

(57) ABSTRACT

An image sensing device is disclosed. The image sensing device includes a substrate including a photoelectric conversion element that produces an electrical signal in response to light incident to the photoelectric conversion element, and a grid structure disposed over the substrate. The grid structure includes a support wall, an air layer disposed at both sides of the support wall, a support cap disposed over the support wall and the air layer, and a capping layer formed over the support wall, the support cap, and the air layer.

### CROSS-REFERENCE TO RELATED APPLICATION

This patent document claims the priority and benefits of Korean patent application No. 10-2019-0123172, filed on Oct. 4, 2019, which is hereby incorporated in its entirety by reference.

### TECHNICAL FIELD

The technology and implementations disclosed in this patent document generally relate to an image sensing device.

### BACKGROUND

An image sensor is a device for converting an optical image into electrical signals. With the increasing development of computer industries and communication industries, demand for high-quality and high-performance image sensors is rapidly increasing in various fields, for example, digital cameras, camcorders, personal communication systems (PCSs), game consoles, surveillance cameras, medical micro-cameras, robots, etc.

### SUMMARY

Various embodiments of the disclosed technology relate to an image sensing device including a grid structure including air that can maintain its shape, and minimize a risk of its collapse due to thermal expansion of the air.

In accordance with an embodiment of the disclosed technology, an image sensing device may include a substrate including a photoelectric conversion element that produces an electrical signal in response to light incident to the photoelectric conversion element, and a grid structure disposed over the substrate. The grid structure may include a support wall, an air layer disposed at both sides of the support wall, a support cap disposed over the support wall and the air layer, and a capping layer formed over the support wall, the support cap, and the air layer.

In another aspect, an image sensing device is provided to include a pixel array including imaging pixels that are arranged in rows and columns and separated by boundary regions located between any two adjacent pixels, each pixel including a photoelectric conversion element that produces an electrical signal in response to light incident to the photoelectric conversion element; a grid structure disposed over the boundary regions and including a support portion and an air-containing layer surrounding the support portion; and a color filter layer disposed between spaces defined by the grid structure, the color filter layer configured to transmit visible light at a certain wavelength to the pixel array.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is an example of a block diagram illustrating an image sensing device based on some implementations of the disclosed technology.

FIG. 2 is a cross-sectional view illustrating an example of a pixel array taken along the line A-A′ shown in FIG. 1 based on some implementations of the disclosed technology.

FIGS. 3A to 3G are cross-sectional views illustrating examples of a buffer layer and a grid structure based on some implementations of the disclosed technology.

FIG. 4 is a conceptual cross-sectional view illustrating a method for removing a sacrificial film pattern by an O₂ plasma process based on some implementations of the disclosed technology.

FIG. 5 is a cross-sectional view illustrating another example of the pixel array taken along the line A-A′ shown in FIG. 1 based on some implementations of the disclosed technology.

### DETAILED DESCRIPTION

The disclosed technology provides various implementations of an image sensing device which can increase light efficiency. Some implementations of the disclosed technology suggest designs of an image sensing device having a grid structure including air that can maintain its shape and minimize a risk of its collapse due to thermal expansion of the air.

Reference will now be made in detail to certain embodiments, examples of which are illustrated in the accompanying drawings. Wherever possible, the same reference numbers will be used throughout the drawings to refer to the same or similar parts. In the following description, a detailed description of related known configurations or functions incorporated herein will be omitted to avoid obscuring the subject matter.

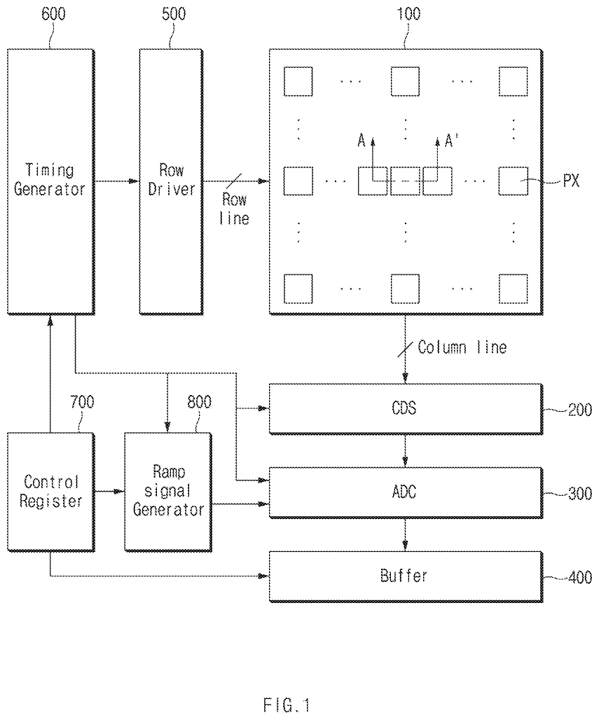

FIG. 1 is an example of a block diagram illustrating an image sensing device based on some implementations of the disclosed technology.

Referring to FIG. 1, the image sensing device may include a pixel array 100, a correlated double sampler (CDS) 200, an analog-to-digital converter (ADC) 300, a buffer 400, a row driver 500, a timing generator 600, a control register 700, and a ramp signal generator 800.

The pixel array 100 may include a plurality of unit pixels (PXs) consecutively arranged in a column direction and in a row direction. Each of the unit pixels (PXs) may convert optical image information into an electrical image signal (pixel signal), and may output the pixel signal to the correlated double sampler (CDS) 200 through column lines. The unit pixels (PXs) may be coupled to row and column lines. The unit pixels (PXs) may include a red pixel, a green pixel, and a blue pixel.

In some implementations, the image sensing device may use the correlated double sampler (CDS) to remove an offset value of pixels by sampling a pixel signal twice so that the difference is taken between these two samples. For example, the correlated double sampler (CDS) may remove an offset value of pixels by comparing pixel output voltages obtained before and after light is incident on the pixels, so that only pixel signals based on the incident light can be actually measured. The correlated double sampler (CDS) 200 may hold and sample electrical image signals received from the unit pixels (PXs) of the pixel array 100 through column lines. For example, the correlated double sampler (CDS) 200 may perform sampling of a reference voltage level and a voltage level of the received electrical image signal in response to a clock signal received from the timing generator 600, and may transmit an analog signal corresponding to a difference between the reference voltage level and the voltage level of the received electrical image signal to the analog-to-digital converter (ADC) 300.

The analog-to-digital converter (ADC) 300 may convert received analog signals into digital signals, and may transmit the digital signals to the buffer 400. In some implementations, the ADC 300 may use a reference signal (e.g., ramp signal) to sample an input signal (e.g., pixel signal) multiple times using the reference signal and analog-to-digital convert the sampled input signals by counting the number of clock pulses until crossing points. For example, the ADC 300 may count clock pulses during a period of time when the input signal is above the reference signal and stop counting clock pulses upon detection of a crossing point (crossing of the reference signal and the input signal).

The buffer 400 may store or latch each of the digital signals received from the analog-to-digital converter (ADC) 300, may amplify each of the latched digital signals, and may output each of the amplified digital signals to an external image signal processor. Therefore, the buffer 400 may include a memory (not shown) for storing or latching the digital signals and a sense amplifier (not shown) for amplifying the digital signals.

The row driver 500 may drive the unit pixels (PXs) of the pixel array 100 in response to an output signal of the timing generator 600. For example, the row driver 500 may generate a selection signal capable of selecting any one of the plurality of row lines.

The timing generator 600 may generate a timing signal to control the row driver 500, the correlated double sampler (CDS) 200, the analog-to-digital converter (ADC) 300, and the ramp signal generator 800.

The control register 700 may generate control signals to control the ramp signal generator 800, the timing generator 600, and the buffer 400.

The ramp signal generator 800 may generate a ramp signal that will be compared with electrical signals (e.g., the sampling signal discussed above) generated by pixels in response to a control signal received from the timing generator 600.

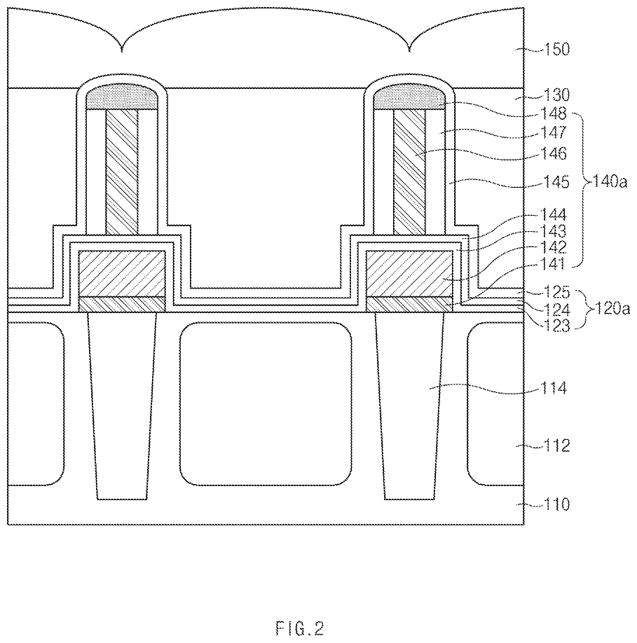

FIG. 2 is a cross-sectional view illustrating an example of the pixel array 100 taken along the line A-A′ shown in FIG. 1.

Referring to FIG. 2, the pixel array 100 of the image sensing device may include a substrate 110, a buffer layer 120a, at least one color filter layer 130, a grid structure 140a, and a lens layer 150.

The substrate 110 may include a semiconductor substrate that includes a first surface and a second surface facing the first surface. The semiconductor substrate 110 may include a monocrystalline silicon, or a similar material The substrate 110 may include one or more photoelectric conversion elements 112. The substrate 110 may further include at least one device isolation structure 114 by which the photoelectric conversion elements 112 are isolated from each other.

Each of the photoelectric conversion elements 112 may include an organic or inorganic photosensing elements. Any photosensing elements can be implemented to generate photocharges in response to light. For example, the photosensing elements include photodiodes, photogates, phototransistors, photoconductors, or some other photosensitive structures capable of generating photocharges.

In some implementations, the photoelectric conversion element 112 may include two or more impurity regions vertically stacked within the semiconductor substrate 110. For example, each of the photoelectric conversion elements 112 may include a photodiode in which an N-type impurity region and a P-type impurity region are vertically stacked. The N-type impurity region and the P-type impurity region may be formed by ion implantation. The device isolation structure 114 may be formed as a deep trench isolation (DTI) structure formed when at least one of an insulation film and the air is buried in the substrate 110. Alternatively, the device isolation structure 114 may include a junction isolation structure including high-density P-type impurities.

The buffer layer 120a may operate as a planarization layer to provide an even surface for subsequent fabrication processes where structures formed on the substrate 110 have uneven surfaces. In some implementations, the buffer layer 120a is substantially transparent to light to be detected by the photoelectric conversion elements 112. In addition, the buffer layer 120a may operate as an anti-reflection film to allow incident light received through the color filter layer 130 to pass through the photoelectric conversion elements 112 of the substrate 110. The buffer layer 120a may be formed over the first surface of the substrate 110. For example, the buffer layer 120a may be formed below each of the color filter layers 130, or may be formed below the entirety of the grid structure 140a and the color filter layer 130.

The buffer layer 120a may be formed of or include a multilayer structure formed by stacking different materials having different refractive indexes. For example, the buffer layer 120a may include a multilayer structure formed by stacking a nitride film 123, an oxide film 124, and a capping film 125.

The nitride film 123 may include a silicon nitride film (SiₓN_{y}, where each of ‘x’ and ‘y’ is a natural number) or a silicon oxide nitride film (SiₓO_{y}N_{z}, where each of ‘x’, ‘y’, and ‘z’ is a natural number). The nitride film 123 may be formed of or include the same materials as those of a nitride film 143 of a grid structure 140a to be described later. Although the nitride films 123 and 143 are denoted by different reference numbers according to formation positions of the nitride films 123 and 143, the nitride film 123 and the nitride film 143 may be simultaneously formed by a single process.

The oxide film 124 may include an undoped silicate glass (USG) film. The oxide film 124 may be formed of or include the same material as in an oxide film 144 of the grid structure 140a. Although the oxide films 124 and 144 are denoted by different reference numbers according to formation positions of the oxide films 124 and 144, the oxide films 124 and 144 may be simultaneously formed by a single process.

The capping film 125 may include an ultra low temperature oxide (ULTO) film such as a silicon oxide film (SiO₂). The capping film 125 may include a multilayer structure formed by stacking low-temperature oxide films, or may include a multilayer structure formed by stacking other material films different from the low-temperature oxide films. The capping film 125 may be formed of or include the same materials as those of the capping film 145 of the grid structure 140a. Although the capping films 125 and 145 are denoted by different reference numbers according to formation positions of the capping films 125 and 145 for convenience of description, the capping films 125 and the capping film 145 may be simultaneously formed by a single process.

The color filter layer 130 may include optical filters located above the photoelectric conversion elements 112 to filter the light to be detected by the photoelectric conversion elements 112. In some implementations, the color filter layer 130 may transmit visible light at a certain wavelength while blocking light at other wavelengths. The color filter layer 130 may include a plurality of color filters. Each unit pixel includes at least one color filter and the color filters may be formed to fill the spaces formed along the boundary of the grid structure 140a. The color filter layer 130 may include a plurality of red color filters (Rs), a plurality of green color filters (Gs), and a plurality of blue color filters (Bs). Each red color filter (R) may transmit only red light from among RGB lights of visible light. Each green color filter (G) may transmit only green light from among RGB lights of visible light. Each blue color filter (B) may transmit only blue light from among RGB lights of visible light. The red filters (Rs), the green filters (Gs), and the blue filters (Bs) may be arranged in a Bayer pattern shape. Alternatively, the color filter layer 130 may include a plurality of cyan filters, a plurality of yellow filters, and a plurality of magenta filters.

The grid structure 140a has portions located above corresponding device isolation structures 114 that are disposed between any two adjacent photoelectric conversion elements 112. Any two adjacent photoelectric conversion elements 112 are separated by boundary regions in which the device isolation structures 114 are located and the grid structure 140a is located above the boundary regions. Each grid structure 140a may be located at or around a boundary region of color filters adjacent to each other, and may prevent optical crosstalk from occurring between the color filters. The grid structure 140a may be formed such that it is in contact with sidewalls of the color filters. In some implementations, each grid structure 140a can be formed as a hybrid structure including a lower portion including a metal grid (MRD) and an upper portion including a low-index layer including an air such as an air grid (ARD).

The lower portion of the grid structure 140a, e.g., the metal grid (MRD), may include a barrier metal layer 141 formed over the first surface of the substrate 110, a metal layer 142 formed over the barrier metal layer 141, and insulation films 143 and 144 formed to cap the barrier metal layer 141 and the metal layer 142.

The barrier metal layer 141 may include any one of titanium (Ti) and titanium nitride (TiN), or may include a stacked structure of titanium (Ti) and titanium nitride (TiN). The metal layer 142 may include tungsten (W).

The insulation film 143 may include the nitride film 143, and the insulation film 144 may include the oxide film 144. The insulation films 143 and 144 may be formed to cap the barrier metal layer 141 and the metal layer 142, such that deformation (collapse) of the shape of the barrier metal layer 141 and the metal layer 142 can be prevented in a thermal annealing process. The nitride film 143 may be formed at side surfaces of the barrier metal layer 141 and the metal layer 142 and at a top surface of the metal layer 142. The oxide film 144 may be formed over the nitride film 143, resulting in formation of a stacked structure of the oxide film 144 and the nitride film 143. The nitride film 143 may be formed of or include the same materials as those of the nitride film 123 of the buffer layer 120a, and may be formed simultaneously with the nitride film 123 through a single process. The oxide film 144 may be formed of or include the same materials as those of the oxide film 124 of the buffer layer 120a, and may be formed simultaneously with the oxide film 124 through a single process.

The upper portion of the grid structure 140a, e.g., the air grid (ARD), may include the capping film 145, the support structures 146 and 148, and the air layer 147. The air layer 147 is described as an example of the low-index layer included in the upper portion of the grid structure 140a and other materials than air can be implemented for the low-index layer.

The capping film 145 may be or include a material film formed at an outermost part of the grid structure 140a, and may define a specific region in which the air layer 147 is formed by capping the air layer 147 and the support structures 146 and 148. The capping film 145 may include the same structure as the capping film 125 of the buffer layer 120a, and may be formed simultaneously with the capping film 125. In some implementations, the capping film 145 may be formed to extend below the color filter layer 130, such that the portion located below the color filter layer 130 may be used as some parts of the buffer layer 120a.

The support structures 146 and 148 are located to prevent collapse of the capping film 145, such that the grid structure 140a can maintain its shape. The support structures 146 and 148 may include the support wall 146 and the support cap 148. The support cap 148 may be disposed over the air layer 147 in a manner that the support cap 148 is in contact with an inner surface of the upper part of the capping film 145, such that the support cap 148 can prevent collapse of the capping film 145. The support wall 146 may be located at the center of the air grid (ARD), and may be formed in a barrier shape. The support wall 146 may be provided between a top surface of the metal grid (MRD) and a bottom surface of the support cap 148. The support wall 146 may contact the top surface of the metal grid (MRD) and the bottom surface of the support cap 148. Thus, the top surface of the support wall 146 may be in contact with the bottom surface of the support cap 148, and the bottom surface of the support wall 146 may be in contact with the top surface of the metal grid (MRD). Therefore, the support wall 146 disposed below the support cap 148 may support the support cap 148 in an upward direction thereof, such that the support wall 146 may prevent the support cap 148 from collapsing in a downward direction in a manner that the support cap 148 can be continuously located at an original position thereof.

The support wall 146 can minimize the region occupied by the air layer 147 in the air grid (ARD), such that thermal expansion of the air layer 147 can be minimized. The air in the air grid can be expanded due to thermal expansion, which can cause the collapse of the grid. The support wall 146 is formed in the air grid (ARD) and the existence of the support wall 146 reduces the size of the region that can be occupied by the air layer 147 as compared to the case when the air grid (ARD) is provided without the support wall 146. Since the amount of the air inside the air grid (ARD) is reduced, thermal expansion of the air layer 147 can be minimized.

The support wall 146 may include a carbon-containing spin on carbon (SOC) film. The support cap 148 may operate as an insulation film that is different in etch selectivity from the support wall 146. The support cap 148 may include at least one of a silicon oxide nitride film (SiₓO_{y}N_{z}, where each of ‘x’, ‘y’, and ‘z’ is a natural number), a silicon oxide film (SiₓO_{y}, where each of ‘x’ and ‘y’ is a natural number), or a silicon nitride film (SiₓN_{y}, where each of ‘x’ and ‘y’ is a natural number).

The air layer 147 may be located at both sides of the support wall 146. In some implementations, the air layer 147 may be disposed between the support wall 146 and the capping film 145 at both sides of the support wall 146.

The lens layer 150 may include a plurality of micro-lenses (and/or a plurality of on-chip lenses) disposed over the color filter layers 130 and the grid structure 140a. The plurality of micro-lenses may converge incident light received from the outside and transmit the light to the color filter layers 130.

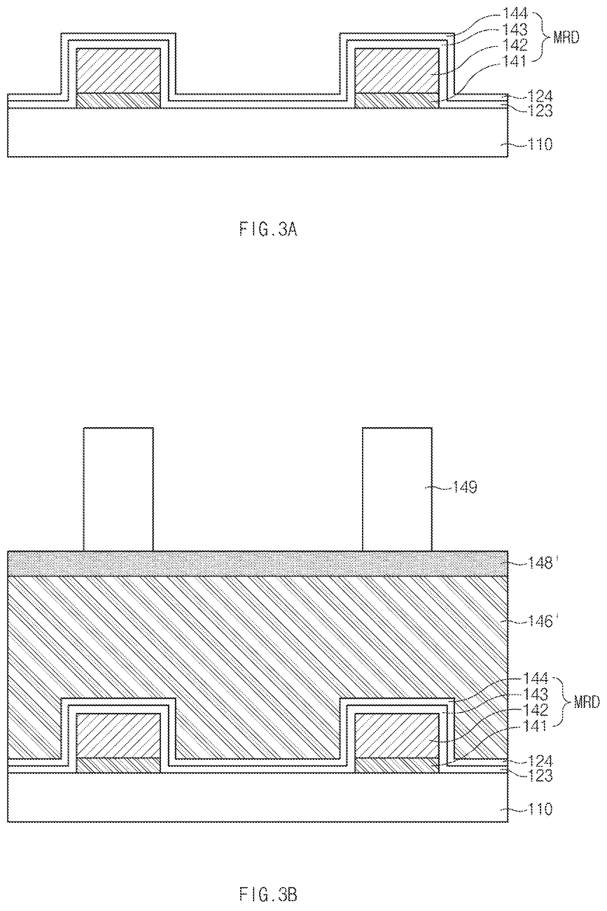

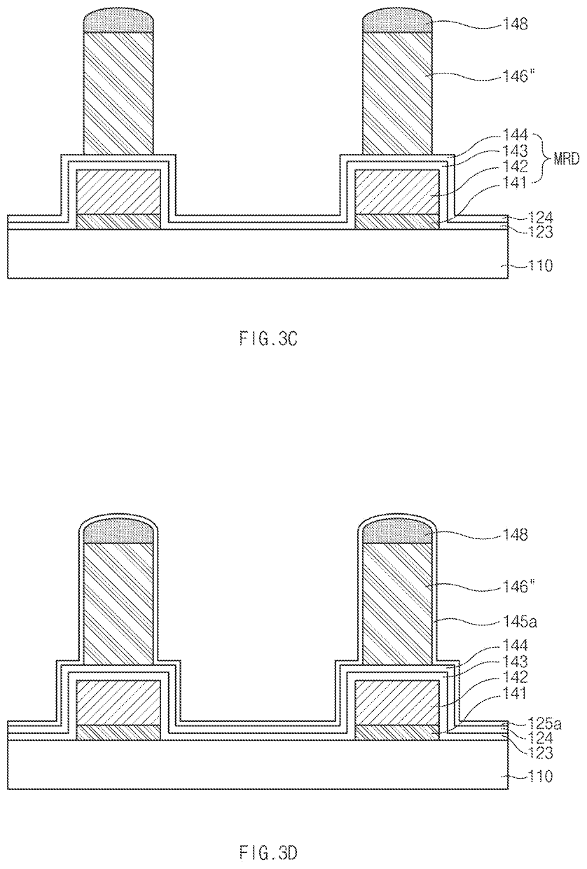

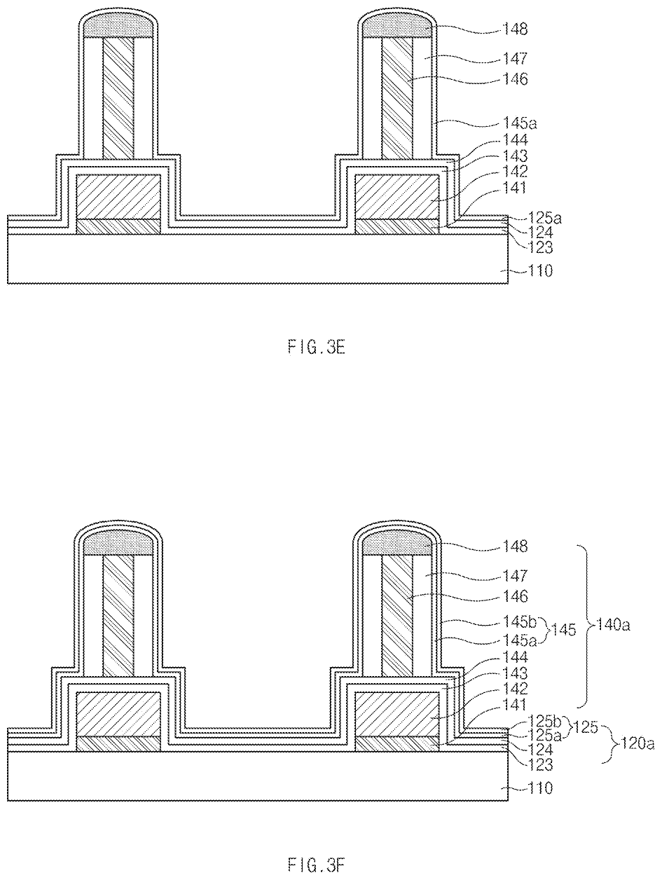

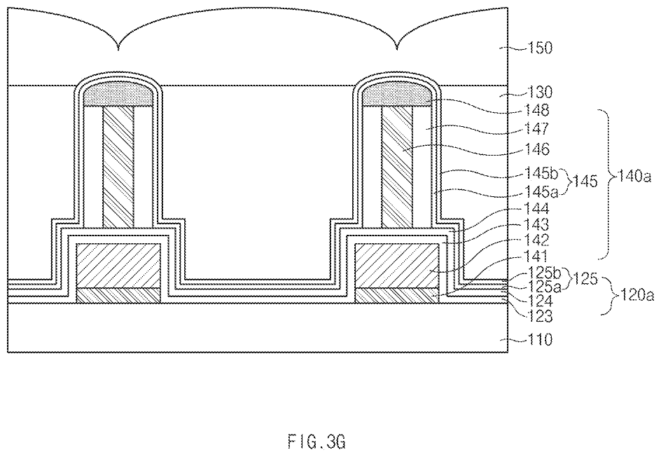

FIGS. 3A to 3G are cross-sectional views illustrating examples of the buffer layer and the grid structure.

Referring to FIG. 3A, a stacked structure of the barrier metal layer 141 and the metal layer 142 may be formed over the substrate 110 including one or more photoelectric conversion elements 112.

For example, after the barrier metal material and the metal material have been sequentially deposited over the substrate 110, the barrier metal material and the metal material may be etched using a mask formed to define a metal grid region, resulting in formation of a stacked structure of the barrier metal layer 141 and the metal layer 142. In some implementations, the barrier metal material may include any one of titanium (Ti) and titanium nitride (TiN), or may include a stacked structure of titanium (Ti) and titanium nitride (TiN). The metal layer may include tungsten (W).

Subsequently, the nitride films 123 and 143 may be formed over the substrate 110 and the barrier metal layer 141, and the metal layer 142, and the oxide films 124 and 144 may be formed over the nitride films 123 and 143, which results in formation of the metal grid (MRD). In some implementations, the nitride film 123 and the oxide film 124 formed over the substrate 110 formed at both sides of the metal grid (MRD) may be used as some parts of the buffer layer 120a.

As discussed above, the nitride films 123 and 143 may also be simultaneously formed by the same deposition process as necessary. In addition, although the oxide films 124 and 144 are denoted by difference reference numbers according to formation positions thereof, the oxide films 124 and 144 may also be simultaneously formed by the same deposition process as necessary. Thus, the nitride film 143 and the oxide film 144 may operate as some parts of the metal grid (MRD), and may be formed over the barrier metal layer 141 and the metal layer 142. The nitride film 123 and the oxide film 124 may operate as some parts of the buffer layer 120a, and may be formed over the substrate 110 formed at both sides of each metal grid (MRD).

Each of the nitride films 123 and 143 may include a silicon nitride film (SiₓN_{y}, where each of ‘x’ and ‘y’ is a natural number) or a silicon oxide nitride film (SiₓO_{y}N_{z}, where each of ‘x’, ‘y’, and ‘z’ is a natural number). Each of the oxide films 124 and 144 may include an undoped silicate glass (USG) film.

Subsequently, the nitride films 123 and 143 and the oxide films 124 and 144 may be annealed. The annealing process may be carried out in a nitrogen (N2) gas environment.

Referring to FIG. 3B, a sacrificial film 146′ may be formed over the oxide films 124 and 144, and a support material layer 148′ may be formed over the sacrificial film 146′.

In some implementations, the sacrificial film 146′ may include a carbon-containing spin on carbon (SOC) film. The support material layer 148′ may be an insulation film that is different from the sacrificial film 146′ in etch selectivity, and may include at least one of a silicon oxide nitride film (SiₓO_{y}N_{z}, where each of ‘x’, ‘y’, and ‘z’ is a natural number), a silicon oxide film (SiₓO_{y}, where each of ‘x’ and ‘y’ is a natural number), or a silicon nitride film (SiₓN_{y}, where each of ‘x’ and ‘y’ is a natural number).

Subsequently, a mask pattern 149 defining a region of the air grid may be formed over the sacrificial film layer 148′.

The mask pattern 149 may include a photoresist pattern.

Referring to FIG. 3C, the support material layer 148′ and the sacrificial film 146′ may be sequentially etched using the mask pattern 149 as an etch mask, such that the mask pattern 149 may be removed. By the above-mentioned process, a stacked structure of the sacrificial film pattern 146″ and the support cap 148 may be formed over the metal grid (MRD).

In some implementations, the upper part of the support cap 148 may be partially etched in the etching process, such that the upper part of the support cap 148 may be formed in a round or curved shape.

Referring to FIG. 3D, the first capping films 145a and 125a may be formed over the resultant structure of FIG. 3C.

Each of the first capping films 145a and 125a may include an oxide film, preferably, a ULTO film. In some implementations, the first capping film 145a may be formed to a predetermined thickness through which molecules formed by combining gas with carbon of the sacrificial film pattern 146″ can be easily discharged outside of the first capping film 145a. In some implementations, the first capping film 145a may be formed to a thickness of 300 Å or less.

Referring to FIG. 3E, the plasma process may be carried out upon the resultant structure of FIG. 3D, such that some parts of the sacrificial film pattern 146″ may be removed and the air layer 147 may be formed at the position from which the sacrificial film pattern 146″ is removed. In some implementations, the plasma process may be carried out using gas (e.g., O₂, N₂, H₂, CO, CO₂, or CH₄) including at least one of oxygen, nitrogen, or hydrogen.

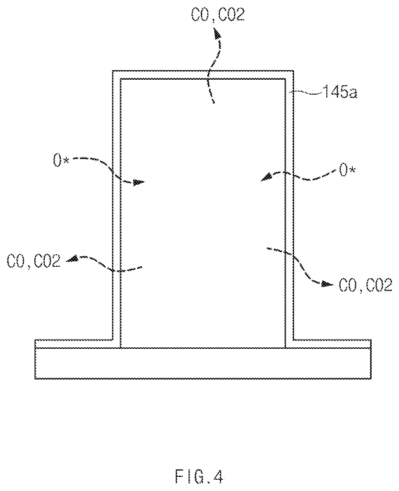

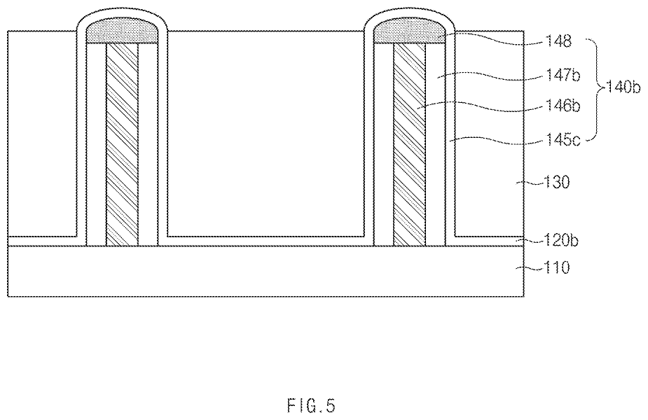

For example, FIG. 4 is a conceptual cross-sectional view illustrating a method for removing the sacrificial film pattern by the O₂ plasma process.

Referring to FIG. 4, if the O₂ plasma process is carried out upon the resultant structure of FIG. 3D, oxygen radicals (O*) may flow into the sacrificial film pattern 146″ through the first capping film 145a, and the oxygen radicals (O*) may be combined with carbons of the sacrificial film pattern 146″, resulting in formation of CO or CO₂. The formed CO or CO₂ may be discharged outside through the first capping film 145a. As a result, the sacrificial film pattern 146″ can be removed, and the air layer 147 may be formed at the position where the sacrificial film pattern 146″ is removed.

In some implementations, the sacrificial film pattern 146″ may be removed or etched from the portion closest to the first capping film 145a to other portions located away from the first capping film 145a. Thus, the portion located farthest from the first capping film may be removed or etched lastly. The O₂ plasma process time may be adjusted in a manner that side portions of the sacrificial film pattern 146″ are etched and the center part of the sacrificial film pattern 146″ remains unetched. Thus, by adjusting the O₂ plasma process time, the support wall 146 can be formed while removing or etching the side portions of the sacrificial film pattern 146″.

During the O₂ plasma process, the support cap 148 remain unetched since the support cap 148 has different etch selectivity from the sacrificial film pattern 146″. Thus, the collapse of the first capping film 145a can be prevented. In addition, the support wall 146, which is formed by adjusting the O₂ plasma process time, can support the support cap 148 and more effectively prevent the collapse of the first capping film 145a.

Referring to FIG. 3F, a second capping film 145b may be formed over the first capping film 145a, and a second capping film 125b may be formed over the first capping film 125a.

When the first capping film 145a is formed to a thick thickness, it may become difficult to remove the sacrificial film pattern 146″ and form the air layer 147 during the O₂ plasma process.

Therefore, to proceed the O₂ plasma process as expected, the first capping film 145a is formed as thin as possible.

When the capping film 145 is formed to a very thin thickness, however, the risk that the capping film 145 is collapsed in a subsequent thermal annealing process due to the expansion of the air layer 147 may increase. Therefore, some implementations of the disclosed technology suggest forming the second capping film 145b over the first capping film 145a after completion of the plasma process. Thus, the capping film 145 has a total thickness including thicknesses of the first capping film 145a and the second capping film 145b. As compared to the case when the capping film 145 is formed with only the first capping film 145a that has a very think thickness, the capping film 145 with a predefined thickness including the first capping film 145a and the second capping film 145b can allow the shape of the grid structure 140a to stably maintain its shape.

In addition, since the air layer 147 has a relatively smaller volume by being provided only at both sides of the support wall 146, the collapse of the capping film 145 due to the thermal expansion of the air layer 147 can be more effectively prevented.

The second capping film 125b may be additionally formed over the first capping film 125a disposed along the boundary of the grid structure 140a, resulting in formation of the buffer layer 120a.

In one implementation, the second capping film 145b and the first capping film 145a may be formed of or include the same materials, and the second capping film 125b and the first capping film 125a may be formed of or include the same materials. In another implementation, the second capping film 145b and the first capping film 145a may be formed of or include different materials, and the second capping film 125b and the first capping film 125a may be formed of or include different materials.

Although the second capping films 145b and 125b have been described as separate structures that are provided at different positions from each other, the second capping films 145b and 125b may be simultaneously formed as a same element by the same deposition process. In addition, the second capping film 145b and the first capping film 145a may be formed under the same fabrication conditions, and the second capping film 125b and the first capping film 125a may be formed under the same fabrication conditions.

Referring to FIG. 3G, the color filter layer 130 may be formed over the buffer layer 120a so as to fill spaces formed along the boundary of the grid structure 140a.

Subsequently, the lens layer 150 may be formed over the color filter layer 130 and the grid structure 140a.

FIG. 5 is a cross-sectional view illustrating another example of the pixel array 100 taken along the line A-A′ shown in FIG. 1 based on implementations of the disclosed technology.

Referring to FIG. 5, the grid structure 140b may include a capping film 145c, support structures 146b and 148, and a low-index layer including an air such as an air layer 147b. Unlike the grid structure 140a shown in FIG. 2, the grid structure 140b shown in FIG. 5 does not include the metal grid (MRD).

The capping film 145c may be identical in structure and material to the above-mentioned capping film 145. Thus, the capping film 145c may include an ultra low temperature oxide (ULTO) film such as a silicon oxide film (SiO₂). The capping film 145c may include a multilayer structure formed by stacking low-temperature oxide films, or may include a multilayer structure formed by stacking other material films different from the low-temperature oxide films. Therefore, the capping film 145c may be formed by the same process as that of the other capping film 145.

The support wall 146b may be located at the center of the grid structure 140b, and may be formed in a barrier shape. The support wall 146b may be located between a top surface of the substrate 110 and a bottom surface of the support cap 148. The support wall 146b may contact the top surface of the substrate 110 and the bottom surface of the support cap 148. Thus, the top surface of the support wall 146b may be in contact with the bottom surface of the support cap 148, and the bottom surface of the support wall 146b may be in contact with the top surface of the substrate 110. The support wall 146b may be formed of the same materials as those of the above-mentioned support wall 146. Therefore, the support wall 146b may be formed by the same process as that of the support wall 146.

The buffer layer 120b may be formed of or include the same materials as those of the capping film 145c of the grid structure 140b. Thus, the capping film 145c may be formed to extend below the color filter layer 130, and the capping film 145c formed between opposite sidewalls of the gird structure 140b and over the substrate 110 may serve as the buffer layer 120b.

The image sensing device as suggested in the embodiments of the disclosed technology has a support structure including a low-index layer such as an air. By doing so, it is possible to maintain the shape of the support structure and minimize the risk of the collapse of the support structure.

The image sensing device according to the embodiments of the disclosed technology may reduce the size of a region (or space) occupied by air in the grid structure, which makes it possible to reduce the affects due to the thermal expansion of the air and prevent the collapse of the grid structure.

Those skilled in the art will appreciate that the embodiments may be carried out in other specific ways than those set forth herein. The above embodiments are therefore to be construed in all aspects as illustrative and not restrictive. In addition, those skilled in the art will understand that claims that are not explicitly cited in each other in the appended claims may be presented in combination as an embodiment or included as a new claim by a subsequent amendment after the application is filed.

What is claimed is:

1. An image sensing device comprising:
a substrate including a photoelectric conversion element that produces an electrical signal in response to light incident to the photoelectric conversion element; and
a grid structure disposed over the substrate,
wherein the grid structure includes:
a support wall;
an air layer disposed at both sides of the support wall;
a support cap disposed over the support wall and the air layer; and
a capping layer formed over the support wall, the support cap, and the air layer.

2. The image sensing device according to claim 1, further comprising:
a metal grid disposed below the support wall and the air layer and above the substrate.

3. The image sensing device according to claim 2, wherein the metal grid includes:
a barrier metal layer;
a metal layer formed over the barrier metal layer; and
an insulation film formed over the barrier metal layer and the metal layer.

4. The image sensing device according to claim 2, wherein:
the support wall is disposed between a top surface of the metal grid and a bottom surface of the support cap.

5. The image sensing device according to claim 1, wherein:
the support wall is disposed between a top surface of the substrate and a bottom surface of the support cap.

6. The image sensing device according to claim 1, wherein the support wall includes a carbon-containing material.

7. The image sensing device according to claim 1, wherein the support wall includes a spin on carbon (SOC) material.

8. The image sensing device according to claim 1, wherein the support cap includes at least one of a silicon oxide nitride film (SiₓO_{y}N_{z}, where each of ‘x’, ‘y’, and ‘z’ is a natural number), a silicon oxide film (SiₓO_{y}, where each of ‘x’ and ‘y’ is a natural number), or a silicon nitride film (SiₓN_{y}, where each of ‘x’ and ‘y’ is a natural number).

9. The image sensing device according to claim 1, wherein the capping layer includes:
a first capping layer formed at side surfaces of the air layer and a top surface and side surfaces of the support cap; and
a second capping layer formed over the first capping layer.

10. The image sensing device according to claim 9, wherein the first capping layer includes an ultra low temperature oxide (ULTO) film.

11. The image sensing device according to claim 1, further comprising:
a color filter layer disposed in spaces formed along the grid structure.

12. The image sensing device according to claim 11, wherein the capping layer is configured to extend to a portion interposed between the color filter layer and the substrate.

13. An image sensing device comprising:
a pixel array including imaging pixels that are arranged in rows and columns and separated by boundary regions located between any two adjacent pixels, each pixel including a photoelectric conversion element that produces an electrical signal in response to light incident to the photoelectric conversion element;
a grid structure disposed over the boundary regions and including a support portion and an air-containing layer surrounding the support portion; and
a color filter layer disposed between spaces defined by the grid structure, the color filter layer configured to transmit visible light at a certain wavelength to the pixel array.

14. The image sensing device of claim 13, wherein the support portion includes a carbon-containing material or a spin on carbon (SOC) material.

15. The image sensing device of claim 13, wherein the grid structure further includes a material layer that is disposed over the support portion and the air-containing layer.

16. The image sensing device of claim 15, wherein the material layer includes at least one of a silicon oxide nitride film, a silicon oxide film, or a silicon nitride film.

17. The image sensing device of claim 13, wherein the grid structure further includes a metal layer that is disposed under the support portion and the air-containing layer.

18. The image sensing device of claim 17, wherein the grid structure further includes an insulation layer disposed above the metal layer and under the support portion and the air-containing layer.

19. The image sensing device of claim 13, further comprising a capping layer covering the grid structure and having a thickness not greater than 300 Å.

20. The image sensing device of claim 19, further comprising an additional capping layer disposed over the capping layer and having a thickness greater than the thickness of the capping layer.
